(19) United States
(12) Patent Application Publication
(10) Pub. No.: US 2025/0241042 A1
(43) Pub. Date: Jul. 24, 2025

(54) SEMICONDUCTOR DEVICE

(71) Applicant: SAMSUNG ELECTRONICS CO., LTD., Suwon-si (KR)

(72) Inventors: Chulsung KIM, Suwon-si (KR); Heesub Kim, Suwon-si (KR); Subin Lee, Suwon-si (KR); Geunhee Jeong, Suwon-si (KR); Sangmin Cho, Suwon-si (KR)

(73) Assignee: SAMSUNG ELECTRONICS CO., LTD., Suwon-si (KR)

(21) Appl. No.: 18/791,974

(22) Filed: Aug. 1, 2024

(30) Foreign Application Priority Data
Jan. 23, 2024 (KR) 10-2024-0010288

(51) Int. Cl. H01L 29/417; H01L 21/8234; H01L 27/088; H01L 29/06; H01L 29/423; H01L 29/66; H01L 29/786

(52) U.S. Cl. CPC H10D 64/258; H10D 30/6735; H10D 30/6757; H10D 62/115; H10D 64/017; H10D 84/0149; H10D 84/038; H10D 84/83

(57) ABSTRACT

A semiconductor device includes: a substrate comprising an active region extending in a first direction; a gate structure extending in a second direction on the substrate, intersecting the first direction and the active region; a source/drain region on a side of the gate structure, on the active region; a contact structure electrically connected to the source/drain region and on the source/drain region; and an insulating structure in contact, in the second direction, with a first contact side surface of the contact structure, wherein at least a portion of the first contact side surface of the contact structure in contact with the insulating structure is inclined such that a width of the contact structure increases toward the substrate.

### CROSS-REFERENCE TO RELATED APPLICATION

This application claims benefit of priority to Korean Patent Application No. 10-2024-0010288, filed on Jan. 23, 2024, in the Korean Intellectual Property Office, the disclosure of which is incorporated herein by reference in its entirety.

### BACKGROUND

### 1. Field

Embodiments of the present disclosure relate to a semiconductor device.

### 2. Brief Description of Background Art

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine separation distance. In addition, in order to overcome a limitation of operating properties due to a reduction in size of a planar metal oxide semiconductor field-effect transistor (MOSFET), efforts have been undertaken to develop semiconductor devices having a channel having a three-dimensional structure.

### SUMMARY

According to embodiments of the present disclosure, a semiconductor device having an improved degree of integration and improved reliability is provided.

According to embodiments of the present disclosure, a semiconductor device is provided and includes: a substrate including an active region extending in a first direction; a gate structure extending in a second direction on the substrate, intersecting the first direction and the active region; a source/drain region on a side of the gate structure, on the active region; a contact structure electrically connected to the source/drain region and on the source/drain region; and an insulating structure in contact, in the second direction, with a first contact side surface of the contact structure, wherein at least a portion of the first contact side surface of the contact structure in contact with the insulating structure is inclined such that a width of the contact structure increases toward the substrate.

According to embodiments of the present disclosure, a semiconductor device is provided and includes: a substrate; a plurality of active regions extending on the substrate in a first direction, the plurality of active regions spaced apart from each other in a second direction, intersecting the first direction; a gate structure extending on the plurality of active regions in the second direction; a plurality of source/drain regions on at least one side of the gate structure on the plurality of active regions; a contact structure extending on the plurality of source/drain regions in the second direction, the contact structure in contact with the plurality of source/drain regions; and an insulating structure on opposite sides of the contact structure in the second direction, the insulating structure in contact with the contact structure, wherein the contact structure including a first portion having a first width in the second direction, and a second portion having a second width greater than the first width, in the second direction, at a level lower than a level of the first portion.

According to embodiments of the present disclosure, a semiconductor device is provided and includes: a substrate including an active region extending in a first direction; a gate structure extending in a second direction, intersecting the first direction and the active region, on the substrate; a plurality of channel layers spaced apart from each other in a third direction, perpendicular to an upper surface of the substrate, on the active region, the plurality of channel layers surrounded by the gate structure; a source/drain region on the active region, on one side of the gate structure, the source/drain region connected to the plurality of channel layers; a plurality of insulating structures on the one side of the gate structure, the plurality of insulating structures overlapping the source/drain region in the third direction, and the plurality of insulating structures including first insulating side surfaces that face each other; and a contact structure in contact with the first insulating side surfaces, the contact structure between the plurality of insulating structures, and the contact structure electrically connected to the source/drain region, on the source/drain region, wherein a distance between the first insulating side surfaces of the plurality of insulating structures increases with an decrease in level in the third direction, and wherein, in a region in which the contact structure and the plurality of insulating structures overlap each other, a width of the contact structure increases with a decrease in level in the third direction.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1A is a schematic plan view of a semiconductor device according to example embodiments;

FIGS. 1B to 1D are schematic cross-sectional views of semiconductor devices according to example embodiments;

FIG. 2 is a schematic cross-sectional view of a semiconductor device according to example embodiments;

FIG. 3 is a schematic cross-sectional view of a semiconductor device according to example embodiments;

FIG. 4 is a schematic cross-sectional view of a semiconductor device according to example embodiments;

FIG. 5A is a schematic plan view of a semiconductor device according to example embodiments;

FIG. 5B is a schematic cross-sectional view of a semiconductor device according to example embodiments;

FIG. 6 is a schematic cross-sectional view of a semiconductor device according to example embodiments;

FIG. 7 is a schematic cross-sectional view of a semiconductor device according to example embodiments;

FIGS. 8A and 8B are schematic process flowcharts of a method of manufacturing a semiconductor device according to example embodiments; and

FIGS. 9-11, 12A-B, 13A-B, 14-16, 17A-B, 18A-B, 19A-B, and 20A-B are cross-sectional views of sequential processes of a method of manufacturing a semiconductor device according to example embodiments.

### DETAILED DESCRIPTION

Hereinafter, non-limiting example embodiments of the present disclosure will be described with reference to the accompanying drawings. Terms such as “top,” “upper portion,” “upper surface,” “above,” “bottom,” “lower portion,” “lower surface,” “below,” and “side surface” may be understood as being referred to based on the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

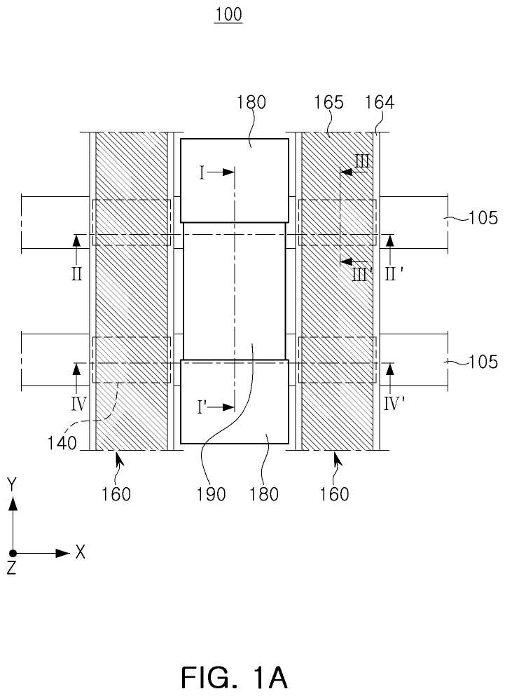

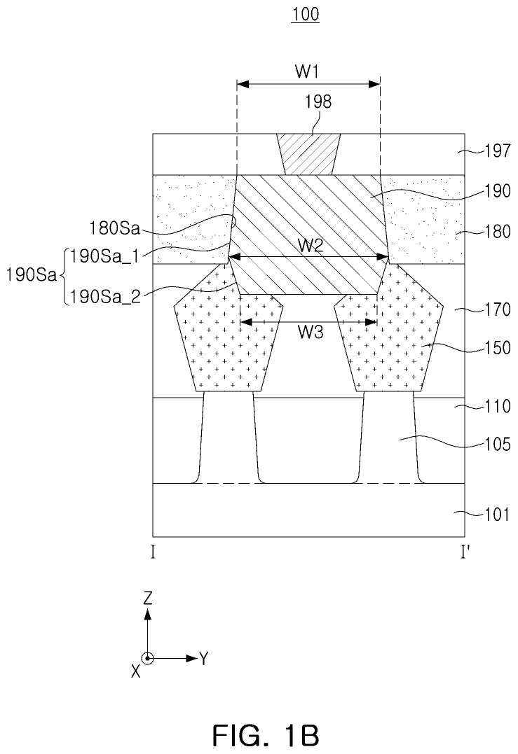

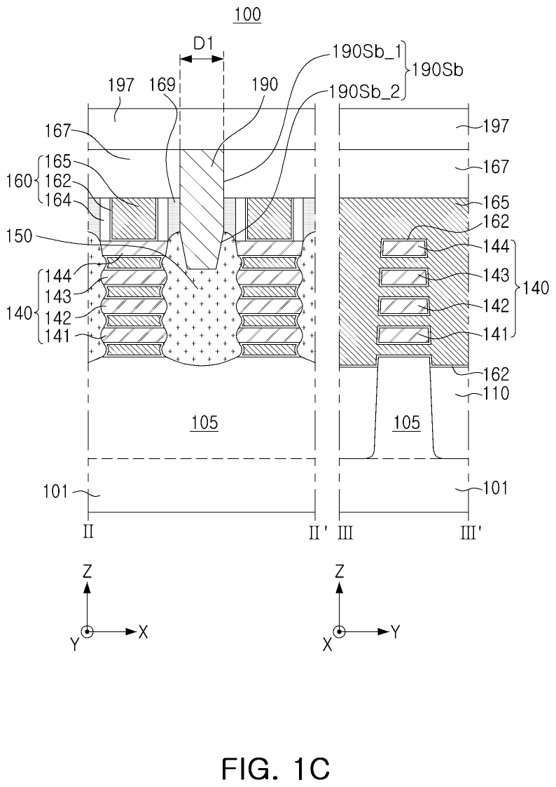

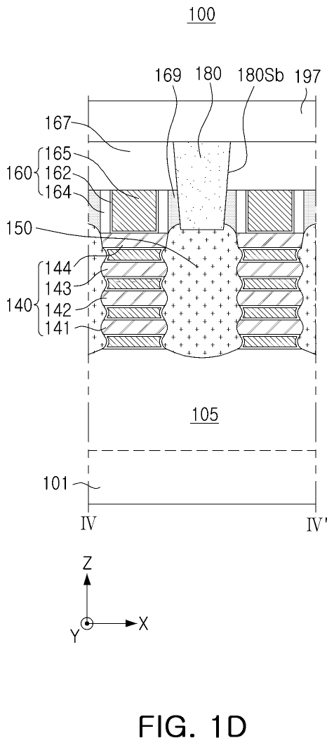

FIG. 1A is a schematic plan view of a semiconductor device according to example embodiments. For ease of description, FIG. 1 illustrates only some components of the semiconductor device. FIG. 1B illustrates a schematic cross-section of the semiconductor device of FIG. 1A, taken along line I-I′. FIG. 1C illustrates schematic cross-sections of the semiconductor device of FIG. 1A, taken along lines II-II′ and lines III-III′. FIG. 1D illustrates a schematic cross-section of the semiconductor device of FIG. 1A, taken along line IV-IV′.

Referring to FIGS. 1A to 1D, a semiconductor device 100 may include a substrate 101 having an active region 105, channel structures 140 including first to fourth channel layers (e.g., a first channel layer 141, a second channel layer 142, a third channel layer 143, and a fourth channel layer 144) disposed on the active region 105 to be vertically spaced apart from each other, gate structures 160 extending to intersect the active region 105 and respectively including a gate electrode 165, source/drain regions 150 in contact with the channel structures 140, insulating structures 180 disposed to form the contact structure 190, and contact structures 190 connected to the source/drain regions 150. The semiconductor device 100 may further include a device isolation layer 110 and an interlayer insulating layer 170.

In the semiconductor device 100, the active region 105 may have a fin structure, and the gate electrode 165 may be between the active region 105 and the channel structure 140, the first to fourth channel layers (e.g., the first channel layer 141, the second channel layer 142, the third channel layer 143, and the fourth channel layer 144) of the channel structure 140, and on the channel structure 140. Accordingly, the semiconductor device 100 may include transistors having a multi bridge channel FET (MBCFET™) structure, gate-all-around type field effect transistors.

The substrate 101 may have an upper surface extending in an X-direction and a Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may have an active region 105 disposed on an upper portion thereof. The active region 105 may be defined by the device isolation layer 110 in the substrate 101, and may be disposed to extend in a first direction, for example, the X-direction. However, depending on a description method, the active region 105 may be described as a separate component from the substrate 101. The active region 105 may partially protrude onto the device isolation layer 110, such that an upper surface of the active region 105 may be positioned on a level that is higher than a level of an upper surface of the device isolation layer 110. The active region 105 may be formed as a portion of the substrate 101, or may include an epitaxial layer grown from the substrate 101. However, on opposite sides of the gate structure 160, the active region 105 may be partially recessed to form recess regions, and the source/drain regions 150 may be disposed in the recess regions.

In example embodiments, the active region 105 may or may not have a well region including impurities. For example, in a P-type transistor (pFET), the well region may include N-type impurities such as phosphorus (P), arsenic (As), or antimony (Sb). In an N-type transistor (nFET), the well region may include P-type impurities such as boron (B), gallium (Ga), or indium (In). For example, the well region may be positioned to have a predetermined depth from the upper surface of the active region 105.

The device isolation layer 110 may define the active region in the substrate 101. The device isolation layer 110 may be formed using, for example, a shallow trench isolation (STI) process. The device isolation layer 110 may expose the upper surface of the active region 105, and may partially expose an upper portion of the active region 105. In some example embodiments, the device isolation layer 110 may have a curved upper surface having a higher level as a distance to the active region 105 gradually decreases. The device isolation layer 110 may be formed of an insulating material. The device isolation layer 110 may include, for example, oxide, nitride, or a combination thereof.

The gate structures 160 may be disposed on the active region 105 and the channel structures 140 to intersect the active region 105 and the channel structures 140 and extend in a second direction (e.g., the Y-direction). Functional channel regions of transistors may be formed in the active region 105 and/or the channel structures 140, intersecting the gate electrodes 165 of the gate structures 160. Each of the gate structures 160 may include a gate electrode 165, gate dielectric layers 162 between the gate electrode 165 and the first to fourth channel layers (e.g., the first channel layer 141, the second channel layer 142, the third channel layer 143, and the fourth channel layer 144), and gate spacer layers 164 on side surfaces of the gate electrode 165. Depending on a description method, gate capping layers 167 and insulating liners 169 may be described as components included in the gate structure 160. However, unless otherwise described, the gate structure 160 is described as a component not included in the gate structure 160.

The gate dielectric layers 162 may be disposed between the active region 105 and the gate electrode 165 and between the channel structure 140 and the gate electrode 165, and may be disposed to cover at least some surfaces, among surfaces of the gate electrode 165. For example, the gate dielectric layers 162 may be disposed to surround surfaces of the gate electrode 165 excluding an uppermost surface of the gate electrode 165. The gate dielectric layers 162 may extend between the gate electrode 165 and the gate spacer layers 164, but embodiments of the present disclosure are not limited thereto. The gate dielectric layers 162 may include oxide, nitride, or a high-κ material. The high-κ material may refer to a dielectric material having a dielectric constant, higher than a dielectric constant of a silicon oxide film (SiO₂). The high-κ material may include, for example, at least one from among aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), and hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some example embodiments, the gate dielectric layer 162 may be formed of a multilayer film.

The gate electrode 165 may be disposed on the active region 105 to fill a space between the first channel layer 141, the second channel layer 142, the third channel layer 143, and the fourth channel layer 144, and to extend onto the channel structure 140. The gate electrode 165 may be spaced apart from the first channel layer 141, the second channel layer 142, the third channel layer 143, and the fourth channel layer 144 by the gate dielectric layers 162. The gate electrode 165 may include a conductive material, for example, a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. In some example embodiments, the gate electrode 165 may include two or more layers.

The gate spacer layers 164 may be disposed on opposite side surfaces of the gate electrode 165, on the channel structure 140. The gate spacer layers 164 may insulate the source/drain regions 150 and the gate electrode 165 from each other. In some example embodiments, the gate spacer layers 164 may have a multilayer structure. The gate spacer layers 164 may be formed of at least one from among oxide, nitride, and oxynitride, and may be formed of, for example, a low-κ film.

The gate capping layer 167 may be disposed on the gate electrode 165, the gate spacer layers 164, and the insulating liners 169. The insulating liners 169 may cover external surfaces of the gate spacer layers 164, and may cover a portion of upper surfaces of the source/drain regions 150. The insulating liners 169 may include a material, different from a material of the interlayer insulating layer 170, and may include a material having an etch selectivity, different from an etch selectivity of the interlayer insulating layer 170. In an example embodiment, the gate spacer layers 164 and the insulating liners 169 may respectively include a plurality of layers. In an example embodiment, the insulating liners 169 may not be present. Depending on a description method, the gate capping layer 167 and the insulating liners 169 may be described as components included in the gate structure 160. For example, when the gate capping layers 167 and the insulating liners 169 are described as components included in the gate structure 160, the insulating structure 180 and the contact structure 190 may also be understood as being in contact with the gate structure 160.

The channel structures 140 may be disposed on the active region 105 in regions in which the active region 105 intersects the gate structures 160. Each of the channel structures 140 may include a first channel layer 141, a second channel layer 142, a third channel layer 143, and a fourth channel layer 144, a plurality of channel layers disposed to be spaced apart from each other in a Z-direction. The first channel layer 141, the second channel layer 142, the third channel layer 143, and the fourth channel layer 144 may be disposed sequentially from a lower portion thereof, and the fourth channel layer 144 may be an uppermost channel layer. The channel structures 140 may be connected to the source/drain regions 150. The channel structures 140 may have a width equal to or similar to a width of the gate structures 160 in the X-direction and may have a width equal to or less than a width of the active region 105 in the Y-direction. In a cross-section in the Y-direction, a lower channel layer, among the first channel layer 141, the second channel layer 142, the third channel layer 143, and the fourth channel layer 144, may have a width equal to or greater than a width of an upper channel layer, among the first channel layer 141, the second channel layer 142, the third channel layer 143, and the fourth channel layer 144. In example embodiments, the number and shape of channel layers, forming a single one of the channel structure 140, may be changed in various manners. For example, the single one of the channel structure 140 may include three channel layers, two channel layers, or five or more channel layers.

The channel structures 140 may be formed of a semiconductor material, and may include, for example, at least one from among silicon (Si), silicon germanium (SiGe), and germanium (Ge). For example, the channel structures 140 may be formed of a material the same as a material of the active region 105. In some example embodiments, the channel structures 140 may have an impurity region, positioned in a region adjacent to the source/drain regions 150.

The source/drain regions 150 may be disposed in recess regions formed by partially recessing an upper portion of the active region 105 on opposite sides of the gate structure 160. The recess regions may extend along side surfaces of the channel structures 140 and side surfaces of the gate dielectric layers 162. The source/drain regions 150 may be disposed to cover side surfaces of each of the first channel layer 141, the second channel layer 142, the third channel layer 143, and the fourth channel layer 144 of the channel structures 140 in the X-direction. Upper surfaces of the source/drain regions 150 may be positioned on a level that is the same as or higher than the level of lower surfaces of the gate electrodes 165 on the channel structures 140. In example embodiments, the level may be changed in various manners. Side surfaces of the source/drain regions 150 may be curved according to the first channel layer 141, the second channel layer 142, the third channel layer 143, the fourth channel layer 144, and the gate structure 160. However, in example embodiments, specific shapes of the side surfaces of the source/drain regions 150 may be changed in various manners. The source/drain regions 150 may be epitaxially grown regions, and an epitaxially grown crystal surface may be in contact with the channel structures 140, the gate structure 160, and the interlayer insulating layer 170. The insulating structure 180 and the contact structure 190 may be disposed to partially recess crystal surfaces of the epitaxially grown source/drain regions 150.

The source/drain regions 150 may include a semiconductor material, for example, at least one from among silicon (Si) and germanium (Ge), and may further include dopants. For example, when the semiconductor device 100 is a pFET, the dopants may be at least one from among boron (B), gallium (Ga), and indium (In). In some example embodiments, the source/drain regions 150 may include a plurality of epitaxial layers.

The interlayer insulating layer 170 may be disposed on the device isolation layer 110 to cover an upper surface of the device isolation layer 110 and the source/drain region 150. The interlayer insulating layer 170 may include at least one from among oxide, nitride, and oxynitride, and may include, for example, a low-κ material. In some example embodiments, the interlayer insulating layer 170 may include a plurality of insulating layers.

The insulating structures 180 may be disposed to recess the interlayer insulating layer 170. Each of the insulating structures 180 may have two side surfaces opposing each other in the first direction (e.g., the X-direction), and two side surfaces opposing each other in the second direction (e.g., the Y-direction). The side surfaces of the insulating structures 180 may be inclined side surfaces such that widths of the insulating structures 180 decrease toward the substrate 101. Among the side surfaces of the insulating structures 180, a side surface, facing the contact structure 190, may be defined as a first insulating side surface 180Sa, and side surfaces, intersecting the first insulating side surface 180Sa and facing the gate structures 160, may be defined as second insulating side surfaces 180Sb. At least a portion of the first insulating side surface 180Sa may be in contact with the contact structure 190. In a third direction (e.g., the Z-direction), perpendicular to an upper surface of the substrate 101, at least a portion of the first insulating side surface 180Sa may overlap the source/drain region 150. The second insulating side surfaces 180Sb may oppose each other in the first direction (e.g., the X-direction). A portion of the second insulating side surfaces 180Sb may be in contact with the gate capping layers 167. A lower surface of the insulating structure 180 may be positioned on a level lower than a level an upper end of the source/drain region 150 and higher than a level of a lower end of the source/drain region 150. The lower surface of the insulating structure 180 may be in contact with the interlayer insulating layer 170. In an example embodiment, the insulating structures 180 may be disposed to partially recess the source/drain regions 150 from upper surfaces of the source/drain regions 150. The interlayer insulating layer 170 may not be present between the first insulating side surface 180Sa of the insulating structures 180 and first upper contact side surface 190Sa_1 of the contact structure 190. In FIG. 1D, it is illustrated that the interlayer insulating layer 170 is not present between the second insulating side surfaces 180Sb of the insulating structure 180 and the insulating liners 169. However, in some example embodiments, a portion of the interlayer insulating layer 170 may be present between the second insulating side surfaces 180Sb and the insulating liners 169. In an example embodiment, a width of each of the insulating structures 180 in the second direction (e.g., the Y-direction) may be 10 nm to 50 nm, or 15 nm to 25 nm. The insulating structures 180 may be, for example, oxide, nitride, or a combination thereof. For example, the insulating structures 180 may include at least one from among SiN, SiON, and SiOCN. In an example embodiment, the insulating structures 180 may include a material different from a material of the interlayer insulating layer 170, and may include a material having an etch selectivity different from an etch selectivity of the interlayer insulating layer 170. For example, the interlayer insulating layer 170 may include silicon oxide (SiO), and the insulating structures 180 may include silicon nitride (SiN).

As a semiconductor device has a higher degree of integration, the insulating structure 180 may be a component for forming the contact structure 190 using a self-aligned process. The insulating structures 180 may include a material having an etch selectivity different from an etch selectivity of the interlayer insulating layer 170, thereby improving reliability of a process of forming the contact structure 190.

The contact structure 190 may be connected to the source/drain regions 150, and may apply an electrical signal to the source/drain regions 150. The contact structure 190 may recess the source/drain regions 150 and extend into the source/drain regions 150. As in the present example embodiment, the contact structure 190 may extend from an upper portion of the channel structure 140 to below a lower surface of the fourth channel layer 144. In some example embodiments, the contact structure 190 may extend below a lower surface of the third channel layer 143 or the second channel layer 142.

The contact structure 190 may be disposed between the insulating structures 180 to recess the interlayer insulating layer 170, and may be disposed to be in contact with the first insulating side surfaces 180Sa of the insulating structures 180. The contact structure 190 may have two side surfaces opposing each other in the first direction (e.g., the X-direction), and two side surfaces opposing each other in the second direction (e.g., the Y-direction). Among the side surfaces of the contact structure 190, side surfaces, facing the insulating structures 180, may be defined as first contact side surfaces 190Sa, and side surfaces, facing the gate structures 160, may be defined as second contact side surfaces 190Sb. The first contact side surfaces 190Sa and the second contact side surfaces 190Sb may intersect each other. Each of the first contact side surfaces 190Sa of the contact structure 190 may include a first upper contact side surface 190Sa_1 in contact with the first insulating side surface 180Sa of the insulating structure 180, and a first lower contact side surface 190Sa_2 extending from a lower portion of the first upper contact side surface 190Sa_1, the first lower contact side surface 190Sa_2 spaced apart from the first insulating side surface 180Sa. The first upper contact side surface 190Sa_1 may extend along the first insulating side surfaces 180Sa, and may be coplanar with the first insulating side surfaces 180Sa. The first upper contact side surface 190Sa_1 may be inclined such that a width of the contact structure 190 increases toward the substrate 101. The first lower contact side surface 190Sa_2 may be inclined such that the width of the contact structure 190 decreases toward the substrate 101. Accordingly, the contact structure 190 may include a first portion having a first width W1 in the second direction (e.g., the Y-direction), a second portion having a second width W2 greater than the first width W1 on a level lower than a level of the first portion, and a third portion having a third width W3 less than the second width W2 on a level lower than the level of the second portion. In an example embodiment, the first portion having the first width W1 may be an upper surface portion of the contact structure 190, the second portion having the second width W2 may be a lower end portion of the first upper contact side surface 190Sa_1, and the third portion having the third width W3 may be a lower surface portion of the contact structure 190.

A portion of the second contact side surfaces 190Sb may be in contact with the insulating liners 169. Each of the second contact side surfaces 190Sb may have a second upper contact side surface 190Sb_1 in contact with the gate capping layer 167 and the insulating liner 169, and a second lower contact side surface 190Sb_2 extending from a lower portion of the second upper contact side surface 190Sb_1, the second lower contact side surface 190Sb_2 having an inclination, different from an inclination of the second upper contact side surface 190Sb_1. At least a portion of the second lower contact side surface 190Sb_2 may be in contact with the source/drain region 150. The second upper contact side surfaces 190Sb_1 may be substantially perpendicular to the upper surface of the substrate 101. The second lower contact side surfaces 190Sb_2 may be inclined such that the width of the contact structure 190 decreases toward the substrate 101.

In an example embodiment, a width D1 of the contact structure 190 in the first direction (e.g., the X-direction) may be 5 nm to 15 nm, or 8 nm to 12 nm. In an example embodiment, a distance between an upper surface and a lower surface of the contact structure 190 may be 20 nm to 50 nm, or 25 nm to 35 nm. The upper surface of the contact structure 190 may be coplanar with an upper surface of the insulating structure 180. For example, the contact structure 190 may include a metal material such as tungsten (W), cobalt (Co), molybdenum (Mo), copper (Cu), ruthenium (Ru), or aluminum (Al).

The first contact side surfaces 190Sa of the contact structure 190 may include the first upper contact side surfaces 190Sa_1 inclined such that the width of the contact structure 190 increases toward the substrate 101, and thus may be stably connected to the source/drain region 150. Accordingly, a semiconductor device having improved reliability may be provided.

An upper insulating layer 197 may cover an upper surface of each of the gate structure 160, the interlayer insulating layer 170, the insulating structure 180, and the contact structure 190. The upper insulating layer 197 may include at least one from among oxide, nitride, and oxynitride, and may include, for example, a low-κ material. In some example embodiments, the upper insulating layer 197 may include a plurality of insulating layers. An upper via 198 may pass through the upper insulating layer 197 to be connected to the contact structure 190. The upper vias 198 may form an interconnection structure on the contact structure 190, and the number of upper vias 198 may be changed in various manners.

In the following descriptions of example embodiments, repeated description overlapping with descriptions provided above with reference to FIGS. 1A to 1D may be omitted.

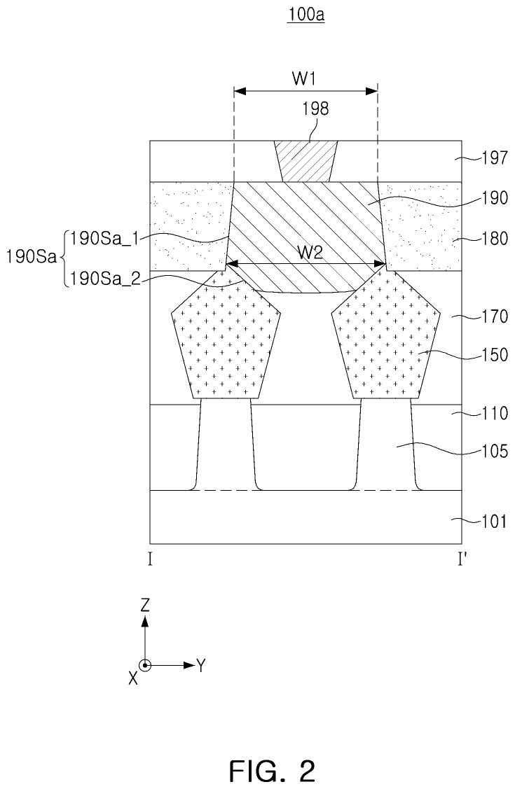

FIGS. 2 to 4 are cross-sectional views of a semiconductor device according to example embodiments. FIGS. 2 to 4 respectively illustrate a region corresponding to a cross-section of the semiconductor device in FIG. 1A, taken along line I-I′.

Referring to FIG. 2, a contact structure 190 of a semiconductor device 100a, unlike the semiconductor device 100 in FIGS. 1A to 1D, may not recess source/drain regions 150, and may be disposed along crystal surfaces of the source/drain regions 150. At least a portion of a first lower contact side surface 190Sa_2 of the contact structure 190 may be formed and disposed along the crystal surfaces of the source/drain regions 150. A lower surface of the contact structure 190 may be convex toward a substrate 101.

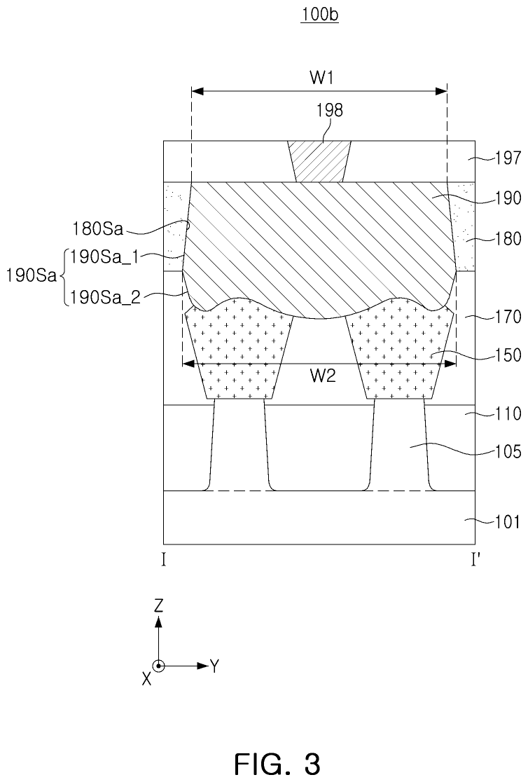

Referring to FIG. 3, in a semiconductor device 100b, unlike the semiconductor device in FIGS. 1A to 1D, an insulating structure 180 may not overlap a source/drain region 150 in a third direction (e.g., a Z-direction), perpendicular to an upper surface of a substrate 101, and may not be in contact with the source/drain region 150. Even in this case, a first insulating side surface 180Sa of the insulating structure 180 may be inclined such that a width of the insulating structure 180 decreases as a level of the insulating structure 180 decreases. A first contact side surface 190Sa of a contact structure 190 may include a first upper contact side surface 190Sa_1 formed along the first insulating side surfaces 180Sa of the insulating structure 180, the first upper contact side surface 190Sa_1 inclined such that a width of the contact structure 190 increases with a decrease in level, and a first lower contact side surface 190Sa_2 extending from a lower portion of the first upper contact side surface 190Sa_1, the first lower contact side surface 190Sa_2 having an inclination, different from an inclination of the first upper contact side surface 190Sa_1. A lower surface of the contact structure 190 may be formed on a level varying depending on a degree of the source/drain regions 150 being recessed, and may be curved. In FIG. 3, it is illustrated that a lower surface of the insulating structure 180 is positioned on a level, higher than a level of the lower surface of the contact structure 190, but embodiments of the present disclosure are not limited thereto. In some example embodiments, the lower surface of the insulating structure 180 may be positioned on a level, lower than a level of the lower surface of the contact structure 190.

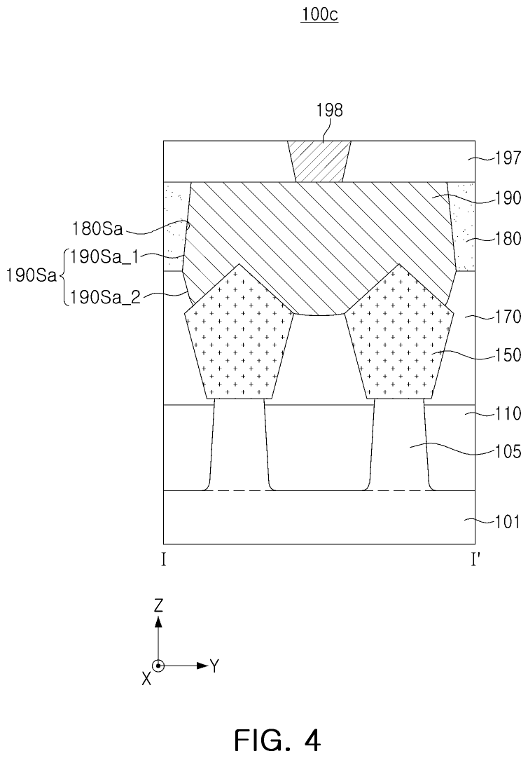

Referring to FIG. 4, in a semiconductor device 100c, unlike the semiconductor device 100b in FIG. 3, a contact structure 190 may not recess source/drain regions 150, and may be disposed along crystal surfaces of the source/drain regions 150. A lower surface of the contact structure 190 may extend along the crystal surfaces of the source/drain regions 150.

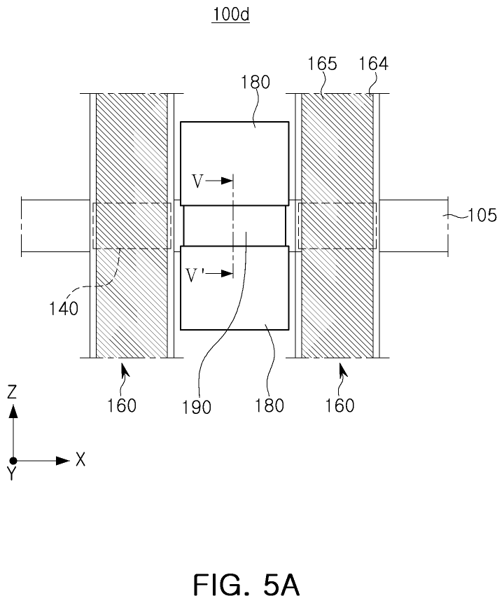

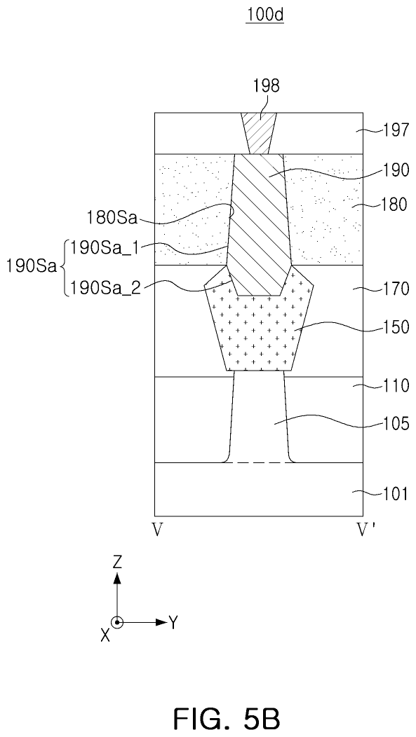

FIG. 5A is a schematic plan view of a semiconductor device according to example embodiments. FIG. 5B illustrates a cross-section taken along line V-V′ of FIG. 5A. For ease of description, FIG. 5A illustrates only some components of the semiconductor device.

Referring to FIGS. 5A and 5B, in a semiconductor device 100d, one contact structure 190 may be connected to one source/drain region 150. In some example embodiments, in the semiconductor device, a contact structure 190 in contact with one source/drain region 150, such as the contact structure 190 of the semiconductor device 100d in FIGS. 5A and 5B, and a contact structure 190 in contact with a plurality of source/drain regions 150 of the semiconductor device 100 of FIG. 1D may be co-present.

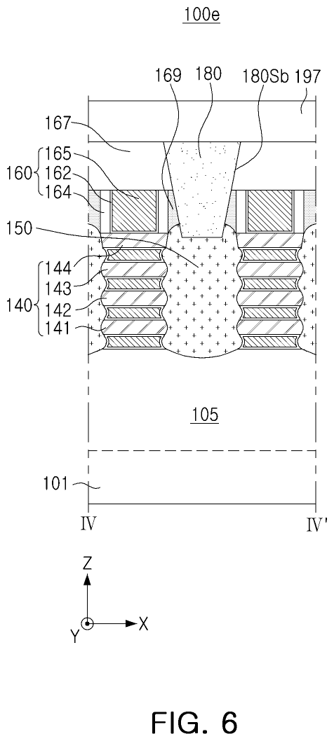

FIG. 6 is a cross-sectional view of a semiconductor device according to example embodiments. FIG. 6 illustrates a region corresponding to a cross-section of the semiconductor device of FIG. 1A, taken along line IV-IV′.

Referring to FIG. 6, in a semiconductor device 100e, an insulating structure 180 may be disposed to recess a portion of a gate capping layer 167 and a portion of insulating liners 169. The insulating structure 180 may be disposed to partially recess a source/drain region 150 from an upper surface of the source/drain region 150. Accordingly, a second insulating side surfaces 180Sb of the insulating structure 180 may be in contact with the gate capping layer 167 and the insulating liners 169. The insulating structure 180 and the gate structure 160 may overlap in a third direction (e.g., a Z-direction), perpendicular to an upper surface of a substrate 101.

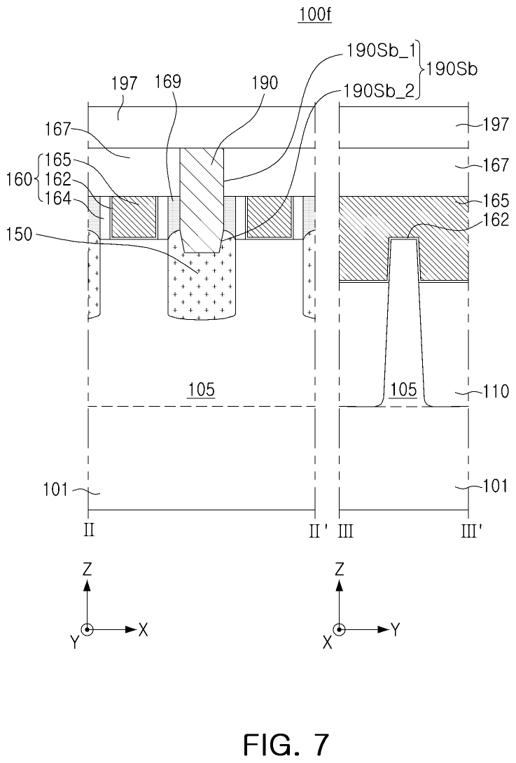

FIG. 7 is a schematic cross-sectional view of a semiconductor device according to example embodiments. FIG. 7 illustrates regions corresponding to FIG. 1B.

Referring to FIG. 7, a semiconductor device 100f, unlike the semiconductor device 100 in FIGS. 1A to 1D, may not include channel structures 140, and accordingly an arrangement of gate structures 160 may be different from the arrangements in the above-described example embodiments. The semiconductor device 100f may include FinFETs, not including a channel layer.

In the semiconductor device 100f, channel regions of transistors may be positioned only in an active region 105 of a fin structure. In addition, channel layers may not be interposed in gate electrodes 165. Accordingly, source/drain regions 150 may not have curved side surfaces corresponding to the gate structure 160 and the channel layers. In addition, the description of components in the example embodiments of FIGS. 1A to 1D may be applied in the same manner to components of the semiconductor device 100f. The semiconductor device 100f may be additionally disposed in regions of semiconductor devices according to other example embodiments.

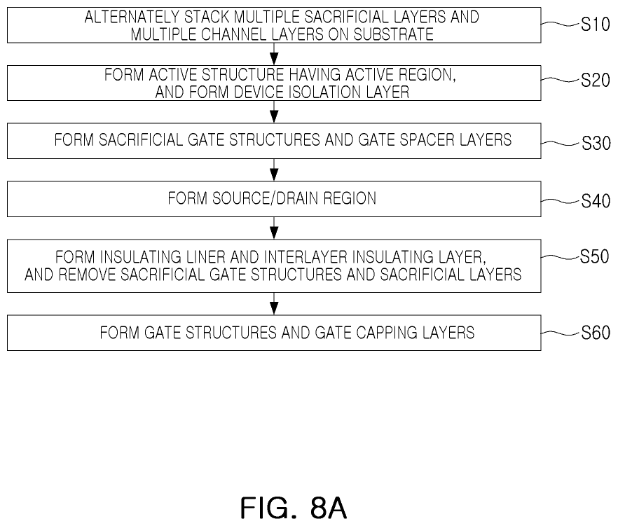

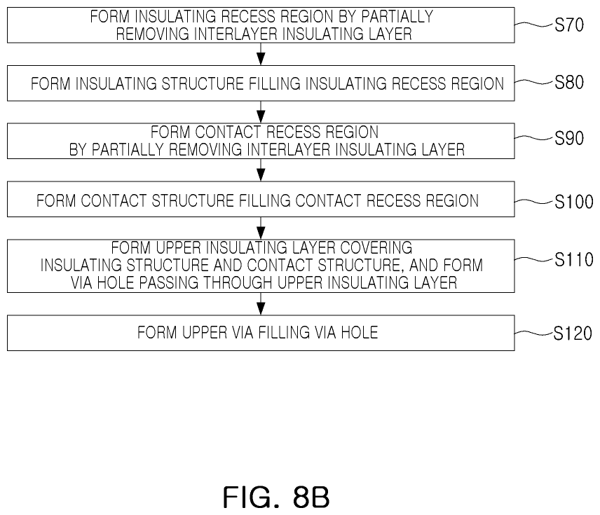

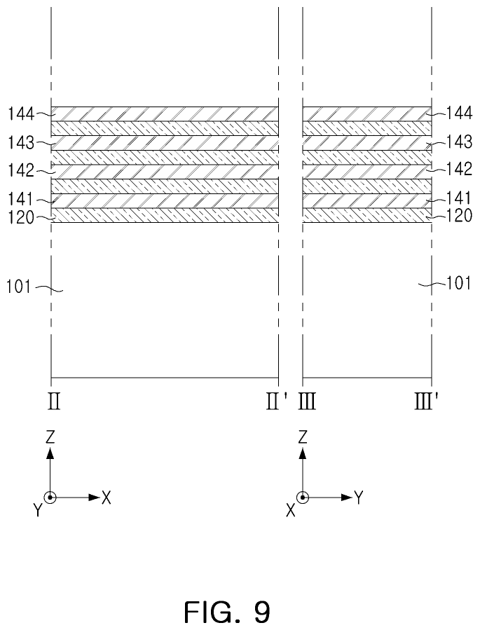

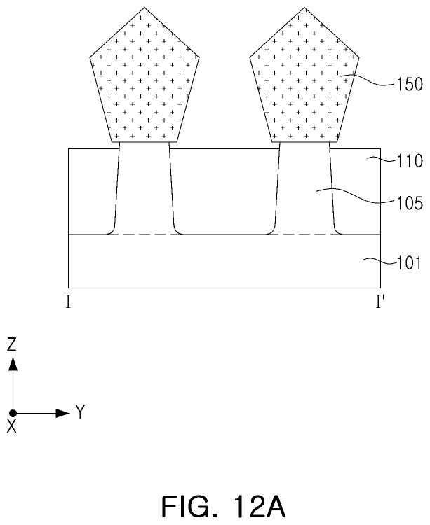

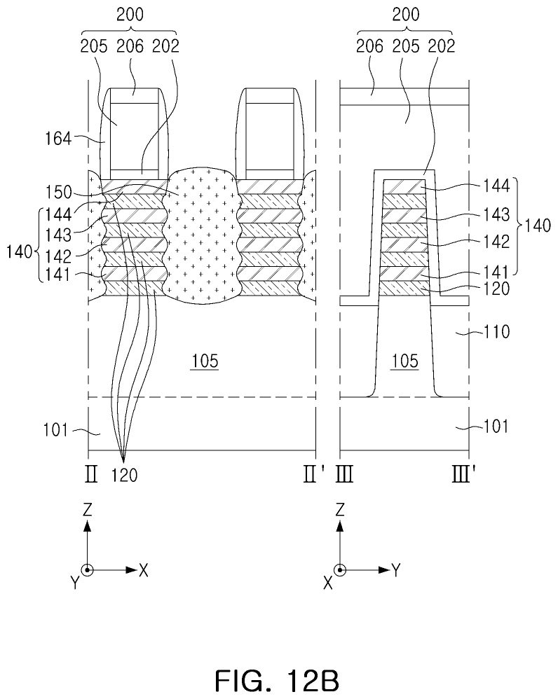

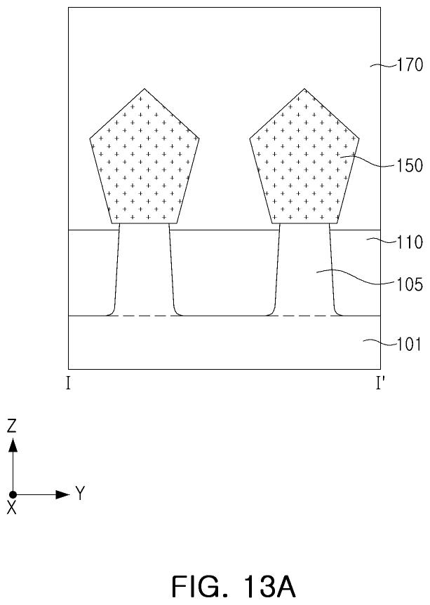

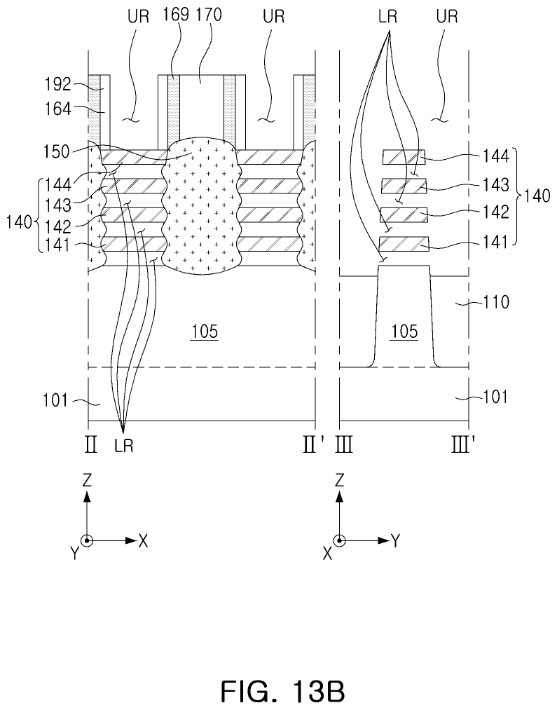

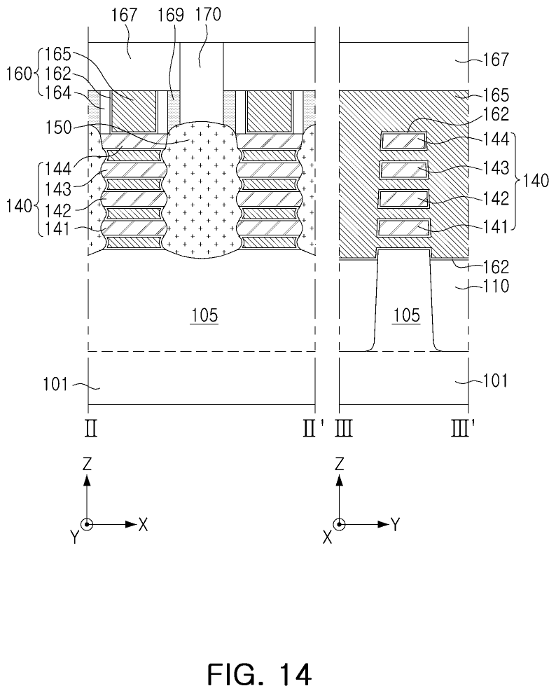

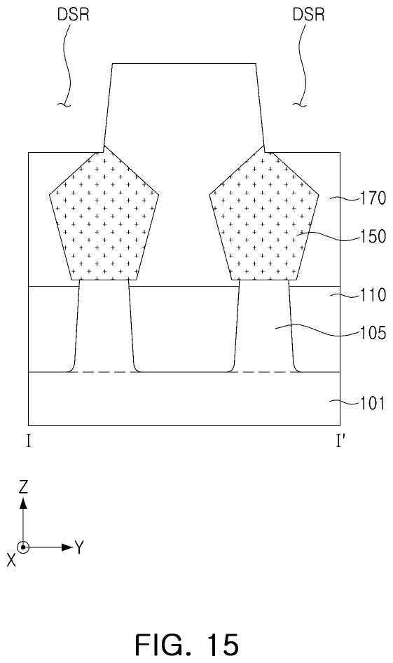

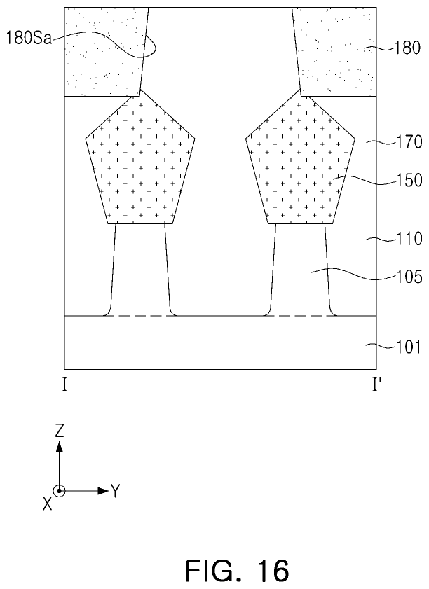

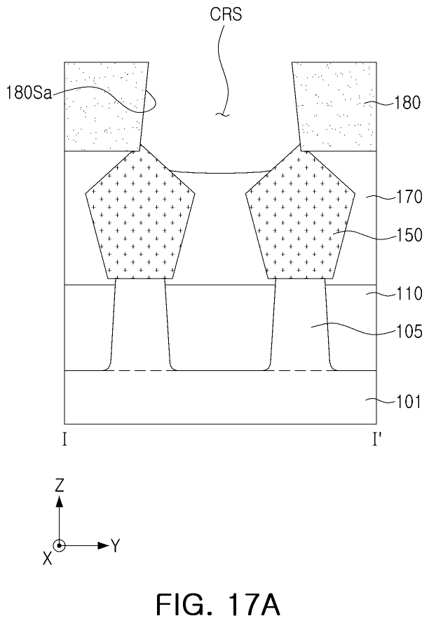

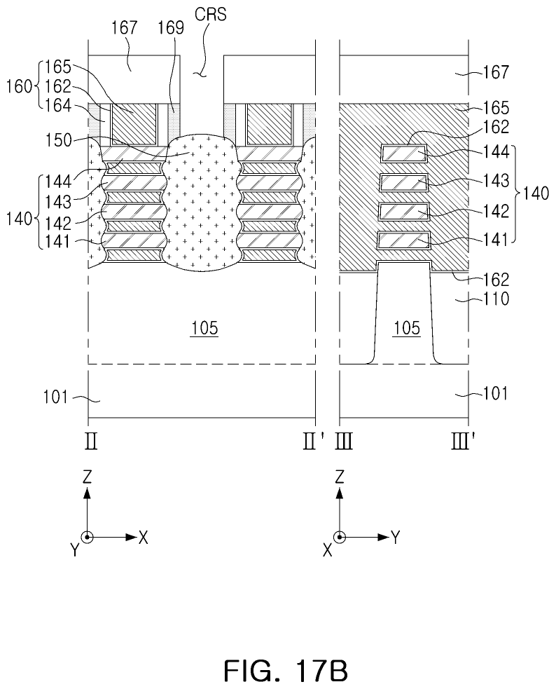

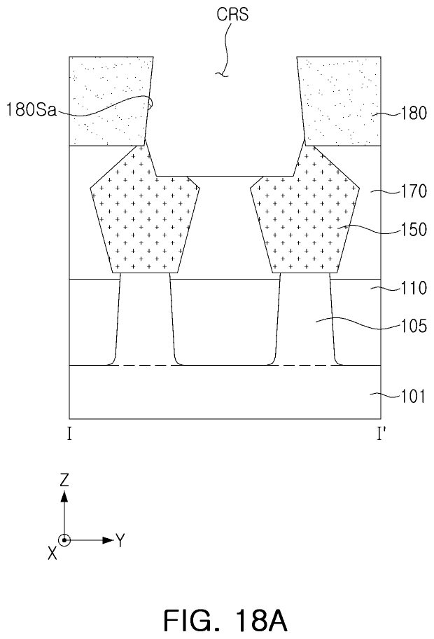

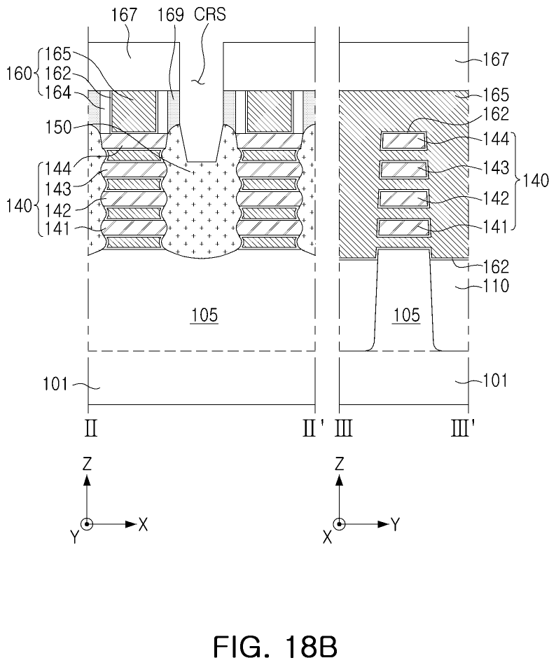

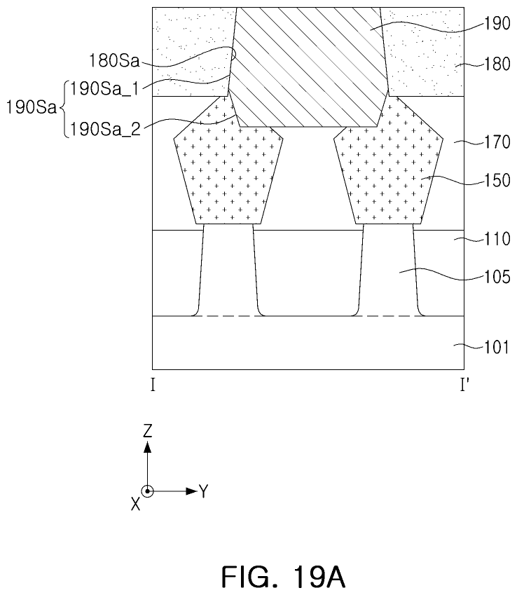

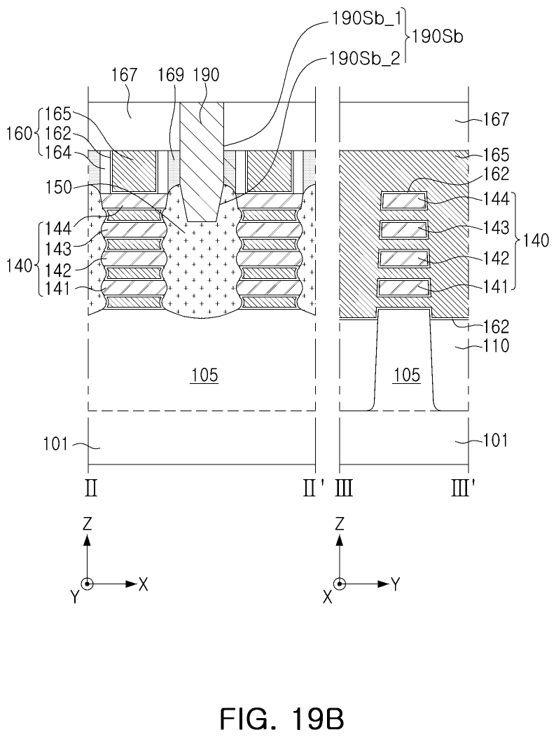

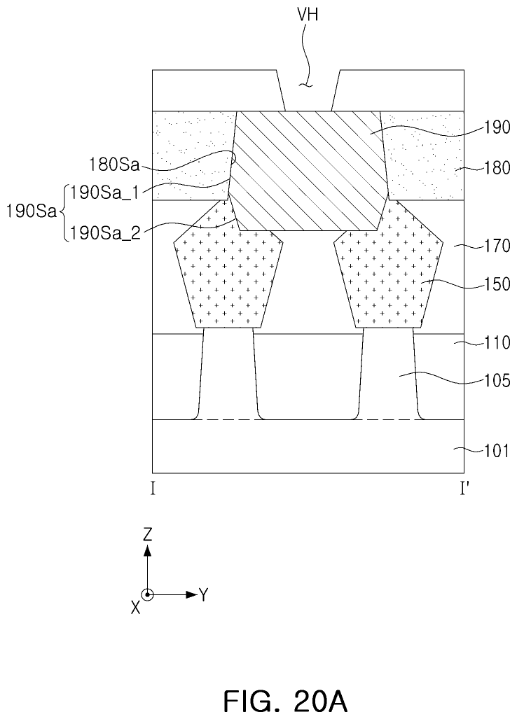

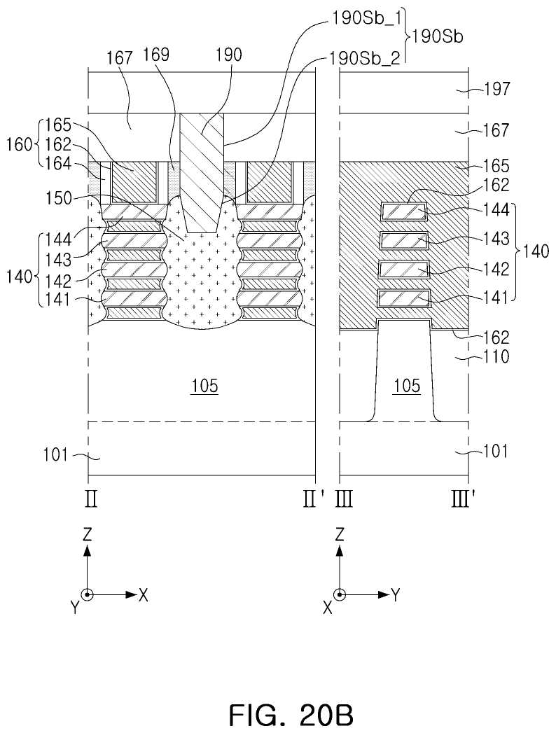

FIGS. 8A to 8B are schematic process flowcharts of a method of manufacturing a semiconductor device according to example embodiments. FIGS. 9 to 20B are cross-sectional views of sequential processes of a method of manufacturing a semiconductor device according to example embodiments. FIGS. 12A, 13A, 15, 16, 17A, 18A, 19A, and 20A illustrate a region corresponding to FIG. 1B, and FIGS. 9 to 11, 12B, 13B, 14, 17B, 18B, 19B, and 20B illustrate a region corresponding to FIG. 1C. The processes may be performed in the order of drawing numbers, and drawings having the same number may indicate processes that may be performed simultaneously. For example, FIGS. 12A and 12B may be cross-sectional views of processes performed simultaneously.

Referring to FIGS. 8A and 9, a plurality of sacrificial layers 120 and a plurality of channel layers (e.g., the first channel layer 141, the second channel layer 142, the third channel layer 143, and the fourth channel layer 144) may be alternately stacked on a substrate 101 (operation S10).

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The plurality of channel layers may include the first channel layer 141, the second channel layer 142, the third channel layer 143, and the fourth channel layer 144. The sacrificial layers 120 may be layers to be replaced with gate dielectric layers 162 and gate electrodes 165 below the fourth channel layer 144 using a subsequent process, as illustrated in FIG. 2. The sacrificial layers 120 may be formed of a material having etch selectivity with respect to the first channel layer 141, the second channel layer 142, the third channel layer 143, and the fourth channel layer 144, respectively. The first channel layer 141, the second channel layer 142, the third channel layer 143, and the fourth channel layer 144 may include a material different from a material of the sacrificial layers 120. The sacrificial layers 120 and the first channel layer 141, the second channel layer 142, the third channel layer 143, and the fourth channel layer 144 may include, for example, a semiconductor material including at least one from among silicon (Si), silicon germanium (SiGe), and germanium (Ge), but may include different materials, and may or may not include impurities. For example, the sacrificial layers 120 may include silicon germanium (SiGe), and the first channel layer 141, the second channel layer 142, the third channel layer 143, and the fourth channel layer 144 may include silicon (Si).

The sacrificial layers 120 and the first channel layer 141, the second channel layer 142, the third channel layer 143, and the fourth channel layer 144 may be formed by performing an epitaxial growth process from the stack structure. In example embodiments, the number of channel layers, stacked alternately with the sacrificial layers 120, may be changed in various manners.

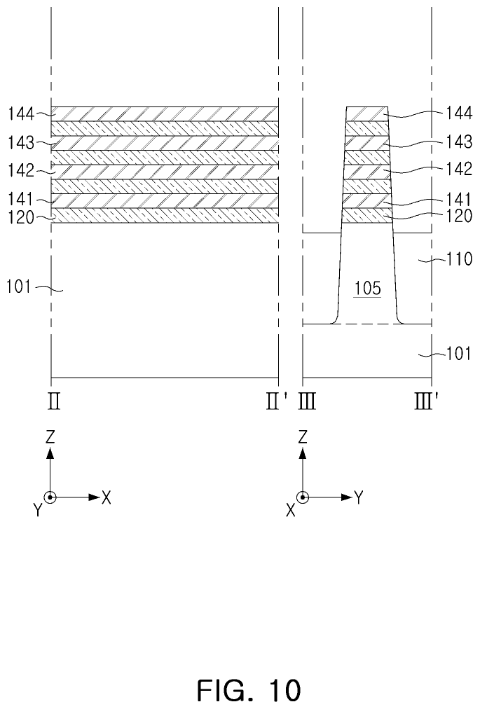

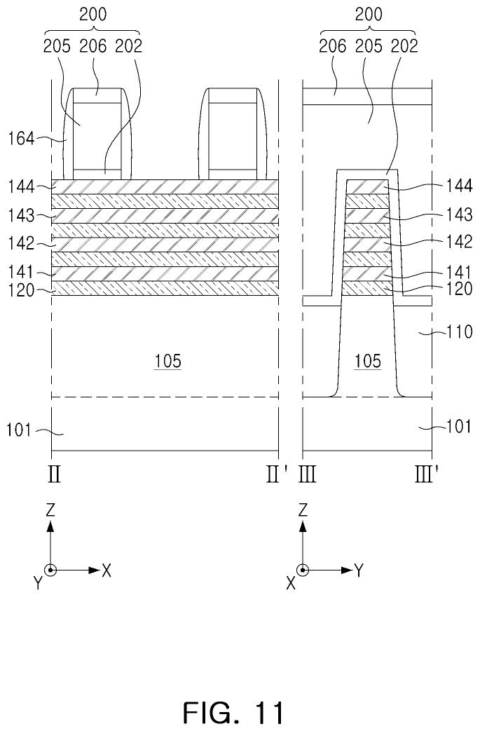

Referring to FIGS. 8A and 10, the sacrificial layers 120, the first channel layer 141, the second channel layer 142, the third channel layer 143, the fourth channel layer 144, and the substrate 101 may be partially removed to form an active structure having an active region 105, and to form a device isolation layer 110 (operation S20).

The active structure may include the active region 105, the sacrificial layers 120, and the first channel layer 141, the second channel layer 142, the third channel layer 143, and the fourth channel layer 144. The active structure may be in the form of a line extending in a direction (e.g., an X-direction), and may be formed to be spaced apart from an active structure adjacent thereto in a Y-direction. Side surfaces of the active structure in the Y-direction may be coplanar with each other, and may be positioned on a straight line.

In a region in which a portion of each of the active region 105, the sacrificial layers 120, and the first channel layer 141, the second channel layer 142, the third channel layer 143, and the fourth channel layer 144 is removed, an insulating material may be filled, and may then be partially removed such that the active region 105 protrudes, thereby forming the device isolation layer 110. An upper surface of the device isolation layer 110 may be formed to be lower than an upper surface of the active region 105.

Referring to FIGS. 8A and 11, sacrificial gate structures 200 and gate spacer layers 164 may be formed on an active structure (operation S30).

Each of the sacrificial gate structures 200 may be a sacrificial structure formed, using a subsequent process, in a region in which gate dielectric layers 162 and a gate electrode 165 are disposed on a channel structure 140, as illustrated in FIG. 2. The sacrificial gate structures 200 may be in the form of a line, intersecting the active structure and extending in a direction. The sacrificial gate structures 200 may extend, for example, in the Y-direction. Each of the sacrificial gate structures 200 may include a first sacrificial gate layer 202, a second sacrificial gate layer 205, and a mask pattern layer 206 that are sequentially stacked. The first sacrificial gate layer 202 and the second sacrificial gate layer 205 may be patterned using the mask pattern layer 206.

The first sacrificial gate layer 202 and the second sacrificial gate layer 205 may be an insulating layer and a conductive layer, respectively, but embodiments of the present disclosure is not limited thereto, and the first sacrificial gate layer 202 and the second sacrificial gate layer 205 may be formed of a single layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on opposite sidewalls of the sacrificial gate structures 200. The gate spacer layers 164 may be formed of a low-κ material, and may include, for example, at least one from among SiO, SiN, SiCN, SiOC, SiON, and SiOCN.

Referring to FIGS. 8A, 12A, and 12B, an etching process may performed using the sacrificial gate structures 200 as an etch mask to form recess regions passing through the active structure and exposing the active region 105. Source/drain regions 150 may be formed in the recess regions (S40).

The sacrificial layers 120 and the first channel layer 141, the second channel layer 142, the third channel layer 143, and the fourth channel layer 144, exposed from the sacrificial gate structures 200, may be partially removed to form recess regions, and to partially remove the sacrificial layers 120. As a result, the first channel layer 141, the second channel layer 142, the third channel layer 143, and the fourth channel layer 144 may form channel structures 140 having a limited length in the X-direction.

The source/drain regions 150 may be formed in the recess regions, and may be grown and formed from side surfaces of the active regions 105 and the channel structures 140 using, for example, a selective epitaxial process. The source/drain regions 150 may include impurities by in-situ doping, and may include a plurality of layers having different doping elements and/or doping concentrations.

Referring to FIGS. 8A, 13A, and 13B, insulating liners 169 and interlayer insulating layers 170 may be formed, and the sacrificial gate structures and the sacrificial layers may be removed (operation S50).

The insulating liners 169 may be formed to extend along side surfaces of the sacrificial gate structures 200 and upper surfaces of the source/drain regions 150. In some example embodiments, the insulating liners 169 may include a plurality of layers. The insulating liners 169 may include a material having an etch selectivity different from an etch selectivity of the interlayer insulating layer 170, or a material harder than a material of the interlayer insulating layer 170. For example, when the interlayer insulating layer 170 includes silicon oxide (SiO), the insulating liners may include silicon nitride (SiN) or silicon carbonitride (SiCN). The interlayer insulating layer 170 may be formed to fill a space between the sacrificial gate structures 200, on the insulating liners 169. The insulating liners 169 and the interlayer insulating layer 170 may be formed to expose the mask pattern layers 206 using a planarization process.

The sacrificial gate structures 200 and the sacrificial layers 120 may be selectively removed with respect to the gate spacer layers 164 and the channel structures 140. First, the sacrificial gate structures 200 may be removed to form upper gap regions UR, and then the sacrificial layers 120, exposed through the upper gap regions UR, may be removed to form lower gap regions LR. For example, when the sacrificial layers 120 include silicon germanium (SiGe) and the channel structures 140 include silicon (Si), the sacrificial layers 120 may be selectively removed with respect to the channel structures 140 by performing a wet etching process.

Referring to FIGS. 8A and 14, the gate structures 160 and the gate capping layers 167 may be formed (operation S60).

The gate structures 160 may be formed to fill the upper gap regions UR and the lower gap regions LR. The gate dielectric layers 162 may be formed to conformally cover internal surfaces of the upper gap regions UR and lower gap regions LR. The gate electrode 165 may formed to completely fill the upper gap regions UR and the lower gap regions LR, and may then be removed from an upper portion thereof to a predetermined depth in the upper gap regions UR. As a result, the gate structures 160, respectively including the gate dielectric layers 162, the gate electrode 165, and the gate spacer layers 164, may be formed.

The gate capping layers 167 may be formed by filling an insulating material in regions in which the gate electrode 165, the gate dielectric layers 162, and the gate spacer layers 164 are removed and performing a planarization process. In example embodiments, relative thicknesses of the gate capping layers 167 and shapes of lower surfaces of the gate capping layers 167 may be changed in various manners.

Referring to FIGS. 8B and 15, insulating recess regions DRS may be formed by partially removing the interlayer insulating layer 170 (operation S70).

The insulating recess regions DRS may be formed by etching the interlayer insulating layer 170 from an upper portion of the interlayer insulating layer 170 in a region in which the insulating structures 180 (see FIG. 1B) are to be formed. In a process of forming the insulating recess regions DRS, the source/drain regions 150 may be partially recessed from upper surfaces thereof. In an example embodiment, the insulating recess regions DRS may be formed using a dry etching process using plasma. The insulating recess regions DRS may be formed to have a downwardly decreasing width.

Referring to FIGS. 8B and 16, the insulating structures 180, filling the insulating recess regions DRS, may be formed (operation S80).

The insulating structures 180 may be formed to fill the insulating recess regions DRS, and may be formed to have inclined side surfaces such that widths thereof decrease with a decrease in level. The insulating structures 180 may be in contact with the source/drain regions 150. However, when the insulating recess regions DRS are formed, the insulating structures 180 may not be in contact with the source/drain regions 150 depending on a depth, position, or the like of the insulating recess regions DRS in an example embodiment.

Referring to FIGS. 8B, 17A, 17B, 18A, and 18B together, the interlayer insulating layer 170 between the insulating structures 180 may be partially removed to form a contact recess region CRS (operation S90).

In an example embodiment, the contact recess region CRS may be formed by partially removing the interlayer insulating layer 170 between the insulating structures 180 in a region in which the contact structure 190 (see FIGS. 1B and 1C) is to be formed, and then partially recessing the source/drain regions 150 from upper surfaces of the source/drain regions 150. That is, the contact recess region CRS may be formed using a plurality of etching processes.

Referring to FIGS. 17A and 17B, the interlayer insulating layer 170 between the insulating structures 180 may be partially etched. In the present operation, the contact recess region CRS may be formed using an isotropic etching process such as a wet etching process or a gas etching process. Depending on a difference in etch selectivity between components, a portion of the interlayer insulating layer 170 may be selectively etched, and the insulating structure 180, the gate capping layers 167, the insulating liners 169, and the source/drain region 150 may not be etched. Accordingly, the contact recess region CRS may be formed along a first insulating side surface 180Sa of the insulating structure 180, side surfaces of the gate capping layers 167, and side surfaces of the insulating liners 169. The first insulating side surface 180Sa may be inclined such that a width of the insulating structure 180 decreases with a decrease in level. Accordingly, a width of the contact recess region CRS in a second direction (e.g., the Y-direction) may be formed to increase. The side surfaces of the gate capping layers 167 and the insulating liners 169 may be substantially perpendicular to an upper surface of the substrate 101, and accordingly a width of the contact recess region CRS in a first direction (e.g., the X-direction) may be substantially constant.

Referring to FIGS. 18A and 18B, the source/drain region 150 may be partially etched from an upper surface thereof to expand the contact recess region CRS. In the present operation, a portion of the interlayer insulating layer 170 may be etched together. In the present operation, an etching process may be performed using an anisotropic etching process, such as a dry etching process using plasma. Accordingly, a level of a region in which the source/drain region 150 is etched may decrease, such that a width of a recess region may decrease. In an example embodiment, the processes in FIGS. 18A to 18B may be omitted. In this case, the semiconductor device 100a in FIG. 2 may be manufactured.

Referring to FIGS. 8B, 19A, and 19B together, a contact structure 190, filling the contact recess region CRS, may be formed (operation S100).

The contact structure 190 may be formed to have a first contact side surface 190Sa facing the insulating structure 180, and the first contact side surface 190Sa may include a first upper contact side surface 190Sa_1 and a first lower contact side surface 190Sa_2. The first upper contact side surface 190Sa_1 may be in contact with the first insulating side surface 180Sa of the insulating structure 180, may be coplanar with the first insulating side surface 180Sa of the insulating structure 180, and may be inclined such that a width of the contact structure 190 increases toward the substrate 101. The first lower contact side surface 190Sa_2 may be inclined such that the width of the contact structure 190 decreases toward the substrate 101. In some example embodiments, after the contact structure 190 is formed, the contact structure 190, the insulating structure 180, and the gate capping layers 167 may be partially etched from upper surfaces thereof using a planarization process.

Referring to FIGS. 8B, 20A, and 20B together, an upper insulating layer 197, covering the contact structure 190 and the insulating structures 180, may be formed, and a via hole VH, passing through the upper insulating layer 197, may be formed (operation S110).

After the upper insulating layer 197, covering the upper surfaces of the contact structure 190, the insulating structure 180, and the gate capping layers 167, is formed, the via hole VH may be formed by removing a portion of the upper insulating layer 197 to expose a portion of the upper surface of the contact structure 190 in a region in which an upper via 198 (see FIG. 1B) is to be formed.

Referring to FIG. 8B together with FIGS. 1B and 1C, the upper via 198, filling the via hole VH, may be formed (operation S120).

The semiconductor device 100 in FIGS. 1A to 1D may be manufactured by forming the upper via 198 filling the via hole VH. In a region not illustrated, a plurality of metal interconnections may be formed on the upper insulating layer 197 and the upper via 198.

According to example embodiments of the present disclosure, a structure of a contact structure connected to a source/drain region may be optimized, such that a semiconductor device may have an improved degree of integration and improved electrical properties.

While non-limiting example embodiments have been shown and described above, it will be apparent to those skilled in the art that modifications and variations could be made without departing from the scope of the present disclosure.

What is claimed is:

1. A semiconductor device comprising:
a substrate comprising an active region extending in a first direction;
a gate structure extending in a second direction on the substrate, intersecting the first direction and the active region;
a source/drain region on a side of the gate structure, on the active region;
a contact structure electrically connected to the source/drain region and on the source/drain region; and
an insulating structure in contact, in the second direction, with a first contact side surface of the contact structure,
wherein at least a portion of the first contact side surface of the contact structure in contact with the insulating structure is inclined such that a width of the contact structure increases toward the substrate.

2. The semiconductor device of claim 1, wherein the insulating structure comprises a first insulating side surface that is in contact with the first contact side surface of the contact structure, and a second insulating side surface intersecting the first insulating side surface, the second insulating side surface facing the gate structure.

3. The semiconductor device of claim 2, wherein the first insulating side surface and the second insulating side surface of the insulating structure are inclined such that a width of the insulating structure decreases toward the substrate.

4. The semiconductor device of claim 1, wherein a lower surface of the insulating structure is at a level that is higher than a level of a lower surface of the contact structure.

5. The semiconductor device of claim 1, wherein the first contact side surface of the contact structure comprises:
a first upper contact side surface in contact with the insulating structure; and
a first lower contact side surface extending from a lower portion of the first upper contact side surface, and
wherein the first lower contact side surface has an inclination that is different from an inclination of the first upper contact side surface.

6. The semiconductor device of claim 5, wherein the first lower contact side surface is inclined such that the width of the contact structure decreases toward the substrate.

7. The semiconductor device of claim 6, wherein the first lower contact side surface is spaced apart from the insulating structure.

8. The semiconductor device of claim 6, wherein at least a portion of the first lower contact side surface is in contact with the source/drain region.

9. The semiconductor device of claim 1, further comprising:
a device isolation layer that defines the active region and is on the substrate; and
an interlayer insulating layer covering at least a portion of the source/drain region, on the device isolation layer,
wherein the insulating structure comprises a material that is different from a material of the interlayer insulating layer.

10. The semiconductor device of claim 9, wherein the insulating structure comprises at least one from among SiN, SiON, and SiOCN.

11. The semiconductor device of claim 1, wherein the width of the contact structure in the first direction is 5 nm to 15 nm.

12. The semiconductor device of claim 1, wherein the contact structure comprises a second contact side surface intersecting the first contact side surface and facing the gate structure, and
wherein at least a portion of the second contact side surface is perpendicular to an upper surface of the substrate.

13. The semiconductor device of claim 12, wherein the second contact side surface comprises:
a second upper contact side surface that is perpendicular to the upper surface of the substrate; and
a second lower contact side surface extending from a lower portion of the second upper contact side surface, the second lower contact side surface inclined such that the width of the contact structure decreases toward the substrate.

14. The semiconductor device of claim 1, wherein a lower surface of the contact structure extends along a crystal surface of the source/drain region, and covers a portion of the crystal surface of the source/drain region.

15. A semiconductor device comprising:
a substrate;
a plurality of active regions extending on the substrate in a first direction, the plurality of active regions spaced apart from each other in a second direction, intersecting the first direction;
a gate structure extending on the plurality of active regions in the second direction;
a plurality of source/drain regions on at least one side of the gate structure on the plurality of active regions;
a contact structure extending on the plurality of source/drain regions in the second direction, the contact structure in contact with the plurality of source/drain regions; and
an insulating structure on opposite sides of the contact structure in the second direction, the insulating structure in contact with the contact structure,
wherein the contact structure comprising a first portion having a first width in the second direction, and a second portion having a second width greater than the first width, in the second direction, at a level lower than a level of the first portion.

16. The semiconductor device of claim 15, wherein the contact structure further comprises a third portion having a third width, in the second direction, less than the second width at a level lower than a level of the second portion.

17. The semiconductor device of claim 16, wherein
a portion of the contact structure, between the first portion and the second portion, has an inclined side surface such that a width of the contact structure increases with a decrease in level, and
a portion of the contact structure, between the second portion and the third portion, has an inclined side surface such that the width of the contact structure decreases with a decrease in level.

18. The semiconductor device of claim 15, wherein
the first portion of the contact structure is an upper surface of the contact structure, and
the second portion of the contact structure is at a level of an upper end of the plurality of source/drain regions.

19. A semiconductor device comprising:
a substrate comprising an active region extending in a first direction;
a gate structure extending in a second direction, intersecting the first direction and the active region, on the substrate;
a plurality of channel layers spaced apart from each other in a third direction, perpendicular to an upper surface of the substrate, on the active region, the plurality of channel layers surrounded by the gate structure;
a source/drain region on the active region, on one side of the gate structure, the source/drain region connected to the plurality of channel layers;
a plurality of insulating structures on the one side of the gate structure, the plurality of insulating structures overlapping the source/drain region in the third direction, and the plurality of insulating structures comprising first insulating side surfaces that face each other; and
a contact structure in contact with the first insulating side surfaces, the contact structure between the plurality of insulating structures, and the contact structure electrically connected to the source/drain region, on the source/drain region,
wherein a distance between the first insulating side surfaces of the plurality of insulating structures increases with an decrease in level in the third direction, and
wherein, in a region in which the contact structure and the plurality of insulating structures overlap each other, a width of the contact structure increases with a decrease in level in the third direction.

20. The semiconductor device of claim 19, wherein a portion of the plurality of insulating structures overlaps a portion of the source/drain region.
